(19) United States
(12) Patent Application Publication
(10) Pub. No.: US 2005/0241578 A1
(43) Pub. Date: Nov. 3, 2005

(54) Oxidizing method and oxidizing unit for object to be processed

(76) Inventors: Kimiya Aoki, Tokyo-To (JP); Keisuke Suzuki, Tokyo-To (JP); Toshiyuki Ikeuchi, Tokyo-To (JP)

Correspondence Address: Smith, Gambrell & Russell, Suite 800, 1850 M Street, N.W., Washington, DC, 20036, US

(21) Appl. No.: 11/072,416

(22) Filed: Feb. 17, 2005

(30) Foreign Application Priority Data
Feb. 25, 2004 (JP) 2004-050514
Jan. 17, 2005 (JP) 2005-009630

(51) Int. Cl. C23C 16/00; B05C 11/00

(52) U.S. Cl. 118/697; 427/255.28

(57) ABSTRACT

The invention is an oxidizing method for an object to be processed, the oxidizing method including: an arranging step of arranging a plurality of objects to be processed in a processing container whose inside can be vacuumed, the processing container having a predetermined length, a supplying unit of an oxidative gas and a supplying unit of a reducing gas being provided at the processing container, each of the plurality of objects to be processed having an exposed silicon layer and an exposed tungsten layer; an active-species forming step of supplying the oxidative gas and the reducing gas into the processing container, causing the both gases to react on each other under a reduced pressure, and generating active oxygen species and active hydroxyl species in the processing container; and an oxidizing step of oxidizing surfaces of the silicon layers of the plurality of objects to be processed by means of the active species.

### FIELD OF THE INVENTION

This invention relates to an oxidizing method and an oxidizing unit for an object to be processed such as a semiconductor wafer or the like, which carries out an oxidation process to a surface of the object to be processed.

### BACKGROUND ART

In general, in order to manufacture a desired semiconductor integrated circuit, various thermal processes including a film-forming process, an etching process, an oxidation process, a diffusion process, a modifying process or the like are carried out to a semiconductor wafer, which consists of a silicon substrate or the like. For example, as an oxidation process, there are known an oxidation process that oxidizes a surface of a single-crystal silicon film or a poly-silicon film, and another oxidation process that oxidizes a metal film, and so on. Such an oxidation process is mainly used for forming an insulation film such as a gate oxide film or a capacitor.

In addition, the above oxidation process may be also conducted for repairing damages or the like in a poly-silicon layer caused by plasma while a gate electrode is formed. Conventionally, as a gate electrode, a laminated structure of a silicon layer, which consists of an impurity-doped poly-silicon, and a tungsten silicide (WSi) layer was adopted. However, in order to achieve a lower resistance, as a gate electrode, a laminated structure of a silicon layer, which consists of an impurity-doped poly-silicon, and a metal layer has started to be adopted. FIGS. 5A and 5B are sectional views of a structural example of a gate electrode having the above poly-silicon-metal structure. As shown in FIG. 5A, a gate oxide film 2 is formed on a surface of an object to be processed W consisting of a single-crystal silicon substrate. On the gate oxide film 2, a silicon layer 4 consisting of an impurity-doped poly-silicon, a barrier metal layer 6 consisting of a WN (tungsten nitride) layer, and a tungsten layer 8 being a metal layer are laminated in that order, in order to form a gate electrode 10. The barrier metal layer has a function of preventing diffusion of Si atom.

Then, in the above gate electrode 10, a plasma etching process is conducted in order to pattern the tungsten layer 8. In the plasma etching process, an exposed surface of the silicon layer 4 is damaged by plasma. In order to repair the damages, after the gate electrode 10 is formed, an oxidation process is conducted as described above.

As shown in FIG. 5B, the oxidation process is conducted for repairing the silicon layer 4 and for forming side-wall layers 12 consisting of SiO₂ films on exposed side surfaces of the silicon layer 4. During the oxidation process, if the tungsten layer 8 is oxidized, the resistance thereof may be increased. Thus, it is necessary to selectively oxidize only the exposed surfaces of the silicon layer 4, inhibiting oxidation of a surface of the tungsten layer which is easy to be oxidized. Thus, as a concrete method of the oxidation process, a moisture vapor oxidation process was mainly used, wherein the oxidation process is conducted by using moisture vapor under a hydrogen(H₂)-rich atmosphere (for example, JP A 4-18727). The mechanism of the selective oxidation process may be thought as follows. That is, the surface of the tungsten layer is once oxidized by the moisture vapor to become an oxidized surface, but the oxidized surface is reduced by the rich H₂ gas to return to tungsten. On the other hand, in the SiO₂ films (side-wall layers 12) formed by oxidizing the surfaces of the silicon layer 4, a bonding force of the oxygen is so strong that the SiO₂ films are not reduced, but remain as they are. Thus, as a result, a selective oxidation process is conducted.

Herein, according to the above oxidation process, the oxidative effect is weak, because it is necessary to inhibit the oxidation of the surface of the tungsten layer 8 as much as possible. In addition, since the process temperature is low, for example about 850° C., as shown in FIG. 5B, an ambient portion of a boundary of the gate oxide film 2 and the silicon layer 4 is oxidized, so that so-called bird's-beaks 14 may be formed.

In order to inhibit the generation of the bird's-beaks 14, it may be thought that it is effective to raise the process temperature for example to 900 to 950° C. so as to strengthen the oxidative effect. However, in that case, because of the high temperature, impurities doped in the silicon layer 4 may diffuse, so that density distribution of the impurities may be changed. Alternatively, although there is the barrier metal layer 6 consisting of the WN film, silicon atoms may diffuse, so that the tungsten film 8 may be bonded to silicon to become a silicide. Thus, the resistance of the gate electrode 10 may be increased.

### SUMMARY OF THE INVENTION

This invention is developed by focusing the aforementioned problems in order to resolve them effectively. The object of this invention is to provide an oxidizing method and an oxidizing unit for an object to be processed, wherein a surface of a silicon layer can be selectively and efficiently oxidized, without raising a process temperature, while inhibiting oxidation of a tungsten layer.

The inventors have studied and studied a selective oxidation process of a silicon layer and a tungsten layer. As a result, it was found that an oxidation process under a low pressure using active oxygen species and active hydroxyl species is effective. In addition, it was found that by optimizing density of a hydrogen gas as a reducing gas during the oxidation process, a more preferable selective oxidation process can be achieved and generation of bird's-beaks can be also inhibited.

That is, the present invention is an oxidizing method for an object to be processed, the oxidizing method comprising: an arranging step of arranging a plurality of objects to be processed in a processing container whose inside can be vacuumed, the processing container having a predetermined length, a supplying unit of an oxidative gas and a supplying unit of a reducing gas being provided at the processing container, each of the plurality of objects to be processed having an exposed silicon layer and an exposed tungsten layer; an active-species forming step of supplying the oxidative gas and the reducing gas into the processing container, causing the both gases to react on each other under a reduced pressure, and generating active oxygen species and active hydroxyl species in the processing container; and an oxidizing step of oxidizing surfaces of the silicon layers of the plurality of objects to be processed by means of the active species.

According to the invention, since the oxidative gas and the reducing gas are used and they are caused to react on each other under a reduced pressure in order to generate the active oxygen species and the active hydroxyl species, for the objects to be processed having the exposed silicon layers and the exposed tungsten layers, the surfaces of the silicon layers can be selectively and efficiently oxidized, and also generation of defectives such as bard's-beaks can be remarkably inhibited.

For example, the oxidizing step is conducted under a process pressure not higher than 466 Pa (3.5 Torr).

In addition, preferably, density of the reducing gas in total of the oxidative gas and the reducing gas is not less than 75% and less than 100%.

In addition, for example, the oxidizing step is conducted under a process temperature within a range of 450° C. to 900° C.

In addition, for example, the oxidative gas includes one or more gases selected from a group consisting of O₂, N₂O, NO, NO₂ and O₃, and the reducing gas includes one or more gases selected from a group consisting of H₂, NH₃, CH₄, HCl and deuterium.

In addition, the present invention is an oxidizing unit comprising: a processing container whose inside can be vacuumed, the processing container having a predetermined length; a supplying unit of an oxidative gas that supplies an oxidative gas into the processing container; a supplying unit of an reducing gas that supplies a reducing gas into the processing container; a holding unit that supports a plurality of objects to be processed at a predetermined pitch, and that can be arranged in the processing container, each of the plurality of objects to be processed having an exposed silicon layer and an exposed tungsten layer; and a controlling unit that controls the supplying unit of an oxidative gas and the supplying unit of an reducing gas so as to control respective supply flow rates of the oxidative gas and the reducing gas into the processing container in such a manner that the silicon layers of the plurality of objects to be processed are selectively oxidized.

According to the invention, since the oxidative gas and the reducing gas are used and their supply flow rates are suitably controlled, for the objects to be processed having the exposed silicon layers and the exposed tungsten layers, the surfaces of the silicon layers can be selectively and efficiently oxidized, and also generation of defectives such as bard's-beaks can be remarkably inhibited.

In addition, the present invention is a controlling unit for controlling an oxidizing unit including: a processing container whose inside can be vacuumed, the processing container having a predetermined length; a supplying unit of an oxidative gas that supplies an oxidative gas into the processing container; a supplying unit of an reducing gas that supplies a reducing gas into the processing container; and a holding unit that supports a plurality of objects to be processed at a predetermined pitch, and that can be arranged in the processing container, each of the plurality of objects to be processed having an exposed silicon layer and an exposed tungsten layer; the controlling unit being adapted to control the supplying unit of an oxidative gas and the supplying unit of an reducing gas so as to control respective supply flow rates of the oxidative gas and the reducing gas into the processing container in such a manner that the silicon layers of the plurality of objects to be processed are selectively oxidized.

Alternatively, the present invention is a program for controlling an oxidizing unit including: a processing container whose inside can be vacuumed, the processing container having a predetermined length; a supplying unit of an oxidative gas that supplies an oxidative gas into the processing container; a supplying unit of an reducing gas that supplies a reducing gas into the processing container; and a holding unit that supports a plurality of objects to be processed at a predetermined pitch, and that can be arranged in the processing container, each of the plurality of objects to be processed having an exposed silicon layer and an exposed tungsten layer; the program being adapted to cause a computer to execute: a controlling procedure for controlling the supplying unit of an oxidative gas and the supplying unit of an reducing gas so as to control respective supply flow rates of the oxidative gas and the reducing gas into the processing container in such a manner that the silicon layers of the plurality of objects to be processed are selectively oxidized.

Alternatively, the present invention is a storage medium capable of being read by a computer, storing the above program.

Alternatively, the present invention is a storage medium capable of being read by a computer, storing software for controlling an oxidizing method for an object to be processed, the oxidizing method comprising: an arranging step of arranging a plurality of objects to be processed in a processing container whose inside can be vacuumed, the processing container having a predetermined length, a supplying unit of an oxidative gas and a supplying unit of a reducing gas being provided at the processing container, each of the plurality of objects to be processed having an exposed silicon layer and an exposed tungsten layer; an active-species forming step of supplying the oxidative gas and the reducing gas into the processing container, causing the both gases to react on each other under a reduced pressure, and generating active oxygen species and active hydroxyl species in the processing container; and an oxidizing step of oxidizing surfaces of the silicon layers of the plurality of objects to be processed by means of the active species.

### BRIEF DESCRIPTION OF THE DRAWINGS

FIG. 1 is a schematic structural view showing an embodiment of an oxidizing unit according to the present invention;

FIG. 2 is a graph showing a relationship between process pressures and film thicknesses of SiO₂ films;

FIGS. 3A to 3C are electron microscope photographs and their sketches showing surfaces of tungsten layers when an H₂-gas density is variously changed for the total flow rate of gases;

FIG. 4 is a graph showing X-ray diffraction spectrums obtained when an X-ray is irradiated on surfaces of tungsten layers; and

FIGS. 5A and 5B are sectional views showing a structural example of gate electrode having a poly-silicon-metal structure.

### DESCRIPTION OF THE PREFERRED EMBODIMENT

Hereinafter, an embodiment of an oxidizing method and an oxidizing unit according to the present invention is explained with reference to attached drawings.

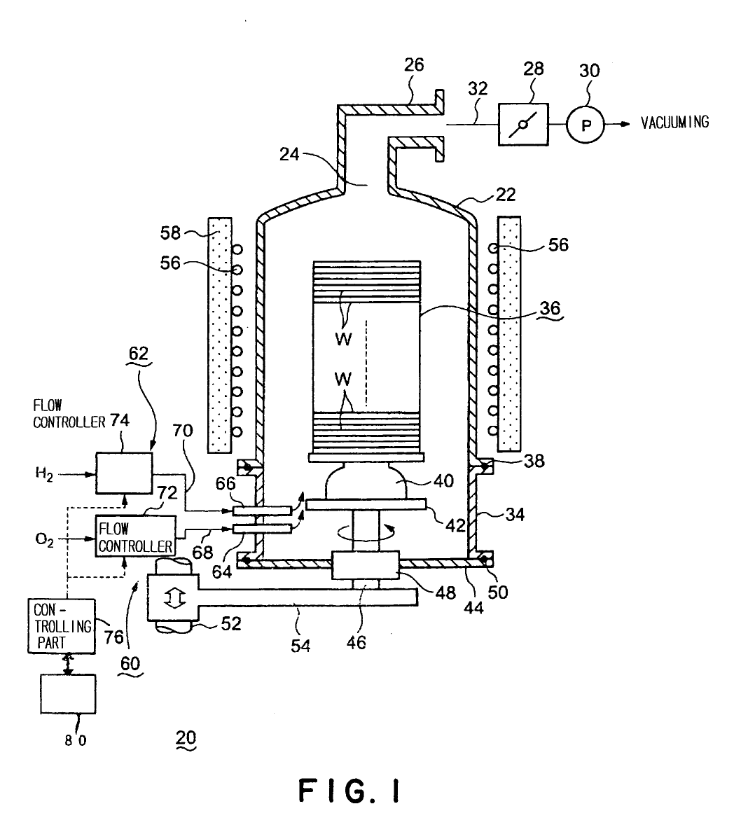

FIG. 1 is a schematic structural view showing the embodiment of an oxidizing unit according to the present invention.

As shown in FIG. 1, an oxidizing unit 20 according to the embodiment of the invention has a cylindrical processing container 22 whose lower end is open. The processing container 22 may be made of for example quartz whose heat resistance is high. The processing container 22 has a predetermined length.

An open gas-discharging port 24 is provided at a ceiling part of the processing container 22. A gas-discharging line 26 that has been bent at a right angle in a lateral direction is provided to connect with the gas-discharging port 24. A gas-discharging system 32 including a pressure-control valve 28 and a vacuum pump 30 and the like on the way is connected to the gas-discharging line 26. Thus, the atmospheric gas in the processing container 22 can be discharged. Herein, the inside of the processing container 22 may be a vacuum or a substantially normal-pressure atmosphere, depending on a process manner.

A lower end of the processing container 22 is supported by a cylindrical manifold 34 made of for example stainless steel. Under the manifold 34, a wafer boat 36 made of quartz as a holding unit, on which a large number of semiconductor wafers W as objects to be processed are placed in a tier-like manner at a predetermined pitch, is provided in a vertically movable manner. The wafer boat 36 can be inserted into and taken out from the processing container 22, through a lower opening of the manifold 34. In the embodiment, for example about 25 to 100 wafers W having a 300 mm diameter may be supported in a tier-like manner at substantially the same interval (pitch) by the wafer boat 36. A sealing member 38 such as an O-ring is interposed between a lower end of the processing container 22 and an upper end of the manifold 34. Thus, airtightness between the processing container 22 and the manifold 34 is maintained.

The wafer boat 36 is placed above a table 42 via a heat-insulating cylinder 40 made of quartz. The table 42 is supported on a top part of a rotation shaft 28 that penetrates a lid member 44 for opening and closing the lower end opening of the manifold 34.

For example, a magnetic-fluid seal 48 is provided at a penetration part of the lid member 44 by the rotation shaft 28. Thus, the rotation shaft 28 can rotate while maintaining airtightness by the lid member 44. In addition, a sealing member 50 such as an O-ring is provided between a peripheral portion of the lid member 44 and a lower end portion of the manifold 34. Thus, airtightness between the lid member 44 and the manifold 34 is maintained, so that airtightness in the processing container 22 is maintained.

The rotation shaft 28 is attached to a tip end of an arm 54 supported by an elevating mechanism 52 such as a boat elevator. When the elevating mechanism 52 is moved up and down, the wafer boat 36 and the lid member 44 and the like may be integrally moved up and down.

Herein, the table 42 may be fixed on the lid member 44. In the case, the wafer boat 36 doesn't rotate while the process to the wafers W is conducted.

A heating unit 56, which consists of for example a heater made of a carbon-wire disclosed in JP A 2003-209063, is provided at a side portion of the processing container 22 so as to surround the processing container 22. The heating unit 56 is capable of heating the semiconductor wafers W located in the processing container 22. The carbon-wire heater can achieve a clean process, and is superior in characteristics of rise and fall of temperature.

A heat insulating material 58 is provided around the outside periphery of the heating unit 56. Thus, the thermal stability of the heating unit 56 is assured.

In addition, various gas-supplying units are provided at the manifold 34, in order to introduce various kinds of gases into the processing container 22.

Specifically, at the manifold 34, an oxidative-gas supplying unit 60 that supplies an oxidative gas into the processing container 22 and a plurality of reducing-gas supplying units 62 that supplies a reducing gas into the processing container 22 are respectively provided.

The oxidative-gas supplying unit 60 has a oxidative-gas ejecting nozzle 64 that pierces the side wall of the manifold 34. A tip portion of the oxidative-gas ejecting nozzle 64 is located in an area on a lower end side in the processing container 22. On the way of a gas passage 68 extending from the oxidative-gas ejecting nozzle 64, a flow-rate controller 72 such as a mass flow controller is provided.

The reducing-gas supplying unit 62 has a reducing-gas ejecting nozzle 66 that pierces the side wall of the manifold 34. A tip portion of the reducing-gas ejecting nozzle 66 is also located in the area on a lower end side in the processing container 22. On the way of a gas passage 70 extending from the reducing-gas ejecting nozzle 66, a flow-rate controller 74 such as a mass flow controller is provided.

Then, a controlling part 76 consisting of a micro computer or the like is adapted to control the respective flow-rate controllers 72 and 74 to control supply flow rates of the respective gases into the processing container 22. When the both gases react on each other, active oxygen species and active hydroxyl species may be generated.

The controlling part 76 has also a function of controlling the whole operation of the oxidizing unit 20. The operation of the oxidizing unit 20, which is described below, is carried out based on commands from the controlling part 76. In addition, the controlling part 76 has a storage medium 80 such as a floppy disk or a flash memory in which a program for carrying out various control operations has been stored in advance. Alternatively, the controlling part 76 is connected (accessible) to the storage medium 80.

Herein, an O₂ gas is used as the oxidative gas, and an H₂ gas is used as the reducing gas. In addition, if necessary, an inert-gas supplying unit, which is not shown but supplies an inert gas such as an N₂ gas, may be provided.

Next, an oxidizing method carried out by using the oxidizing unit 20 is explained. As described above, the operations of the oxidizing unit 20 are carried out based on the commands from the controlling part 76 based on the program stored in the storage medium 80.

When the semiconductor wafers W consisting of for example silicon wafers are unloaded and the oxidizing unit 20 is under a waiting state, the processing container 22 is maintained at a temperature, which is lower than a process temperature. Then, the wafer boat 36 on which a large number of, for example fifty, wafers W of a normal temperature are placed is moved up and loaded into the processing container 22 in a hot-wall state from the lower portion thereof. The lid member 44 closes the lower end opening of the manifold 34, so that the inside of the processing container 22 is hermetically sealed.

As shown in FIG. 5A, the gate electrode 10 mainly consisting of the silicon layer 4 and the tungsten layer 8 is formed on a surface of each semiconductor wafer W. A surface of the silicon layer 4 and a surface of the tungsten layer 8 are exposed. Herein, the silicon layer may include a surface itself of the silicon substrate.

Then, the inside of the processing container 22 is vacuumed and maintained at a predetermined process pressure. On the other hand, electric power supplied to the heating unit 56 is increased so that the wafer temperature is raised and stabilized at a process temperature for the oxidation process. After that, predetermined process gases, herein the O₂ gas and the H₂ gas, are respectively supplied from the gas ejecting nozzle 64 of the oxidative-gas supplying unit 60 and the gas ejecting nozzle 66 of the reducing-gas supplying unit 62 into the processing container 22 while the flow rates of the gases are controlled.

The both gases ascend in the processing container 22 and react on each other in a vacuum atmosphere in order to generate the active hydroxyl species and the active oxygen species. The active species come in contact with the wafers W contained in the rotating wafer boat 36. Thus, the oxidation process is conducted to the wafer surfaces. That is, the surfaces of the silicon layers 4 are oxidized and thus SiO₂ films are formed. On the other hand, the surfaces of the tungsten layers 8 are scarcely oxidized, so that no film is formed. The respective process gases and a reaction product gas are discharged outside from the gas-discharging port 24 at the ceiling part of the processing container 22.

At that time, the total gas flow rate of the H₂ gas and the O₂ gas is within a range of 2000 sccm to 4000 sccm, for example 2000 sccm. Then, density of the H₂ gas in the total gas flow rate is not less than 75% and less than 100%. As described below, if the density of the H₂ gas is less than 75%, not only the surfaces of the silicon layers 4 are oxidized, but also the surfaces of the tungsten layers 8 may be oxidized. The oxidized tungsten layers 8 remain as they are, so that a sufficient selective oxidation process can not be achieved. To the contrary, if the density of the H₂ gas is 100%, the surfaces of the silicon layers 4 can not be oxidized.

As described above, the H₂ gas and the O₂ gas separately introduced into the processing container 22 ascend in the processing container 22 of a hot-wall state, cause a burning reaction of hydrogen in the vicinity of the wafers W, and form an atmosphere mainly consisting of the active oxygen species (O*) and the active hydroxyl species (OH*). These active species oxidize the surfaces of the wafers W so that SiO₂ films are formed. On the other hand, even if the surfaces of the tungsten layers 8 are oxidized, they are immediately reduced by the H₂ gas, so that they are still metal. As a result, a selective oxidation process may be achieved. That is, as shown in FIG. 5B, the side-wall layers 12 are formed on the side surfaces of the silicon layers 4, and plasma damages of the silicon layers 4 are repaired.

Regarding the process condition at that time, the wafer temperature is within 450 to 900° C., for example 850° C., and the pressure is not higher than 466 Pa (3.5 Torr), for example 46.6 Pa (0.35 Torr). In addition, the processing time is for example about 10 to 30 minutes although it depends on a film thickness of the formed film. If the process temperature is lower than 450° C., the above active species (radicals) may not be generated sufficiently. To the contrary, if the process temperature is higher than 900° C., the tungsten layers 8 may react on silicon atoms to become silicide. In addition, if the process pressure is higher than 3.5 Torr, the above active species may not be generated sufficiently. At that time, preferably, the process pressure is not higher than 1 Torr.

Herein, a forming process of the active species is thought as follows. That is, since the hydrogen and the oxygen are separately introduced into the processing container 22 of a hot-wall state under a reduced-pressure atmosphere, it may be thought that the following burning reaction of the hydrogen is promoted near to the wafers W. In the following expressions, chemical symbols with a mark “*” mean active species thereof.
H₂+O₂→H*+HO₂
O₂+H*→OH*+O*
H₂+O*→H*+OH*
H₂+OH*→H*+H₂O

As described above, when the H₂ gas and the O₂ gas are separately introduced into the processing container 22, the O* (active oxygen species) and the OH* (active hydroxyl species) and the H₂O (moisture vapor) are generated during the burning reaction of the hydrogen. These (O*, OH*, H₂O) oxide the surfaces of the silicon layers 4 of the wafers, so that the SiO₂ films are formed. At that time, in particular, it is thought that the O* and the OH* greatly contribute to the oxidation effect.

Then, an actual selective oxidation process was conducted to wafers of silicon substrates, each of which has an exposed silicon layer and an exposed tungsten layer.

<Evaluation Experiment 1>

At first, as an evaluation experiment 1, in order to find a condition to assure selectivity between an oxidation to a surface of the tungsten layer and an oxidation to a surface of the silicon layer, dependency of the film thickness (film-forming rate) on the process pressure was examined.

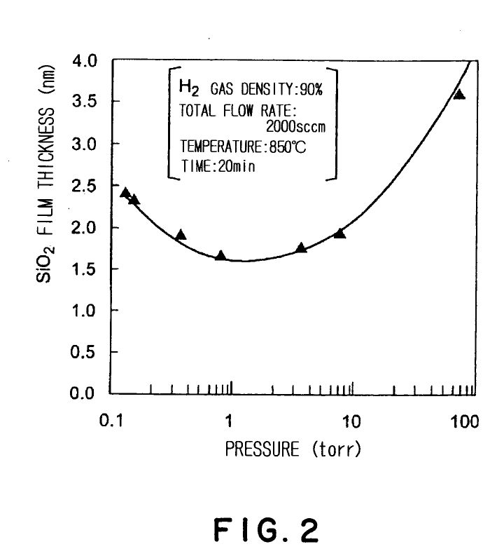

FIG. 2 is a graph showing a relationship between process pressures and film thicknesses of SiO₂ films. Herein, under a condition wherein the density of the H₂ gas is 90%, the process pressure was changed within a range of 0.15 Torr (20 Pa) to 76 Torr (1018 Pa). At that time, the process temperature was 850° C., and the processing time was 20 minutes. Regarding the process gases, the flow rate of the H₂ gas was 1800 sccm, the flow rate of the O₂ gas was 200 sccm, and thus the total flow rate was 2000 sccm.

As clearly seen from FIG. 2, as the process pressure is decreased from 76 Torr, the oxidative effect is also decreased. Thus, the film thickness of the formed SiO₂ film is also gradually reduced. Then, when the process pressure is below 10 Torr, the degree of reduce of the film thickness becomes gradually gentle. To the contrary, below 1 Torr, the film thickness is increased rapidly.

The reason of the above characteristics is as follows. That is, in an area wherein the process pressure is higher than 1 Torr, the moisture vapor is dominant in the atmosphere, so that oxidizing species contributing to the oxidation of the silicon layers are the moisture vapor. On the other hand, when the process pressure is not higher than 1 Torr, active oxygen species and active hydroxyl species are rapidly generated, and then these active species become dominant in the atmosphere. Thus, these active species contribute to the oxidation of the silicon layers as oxidizing species. As described above, since the both active species oxidize the silicon layers as oxidizing species, the film thickness is rapidly increased, although the process pressure is smaller than 1 Torr.

Herein, if only the film thickness is taken into consideration, it may be evaluated that both the case wherein the moisture vapor is oxidizing species and the case wherein the active oxygen species and the active hydroxyl species are oxidizing species are good. However, it can be found by measuring particles on the surfaces of the tungsten layers that the oxidation process in the atmosphere mainly consisting of the moisture vapor is not preferable, but that the oxidation process in the atmosphere wherein the active oxygen species and the active hydroxyl species are oxidizing species is preferable. Actually, the number of particles on the surface of a tungsten layer obtained by each condition of FIG. 2 was counted. Then, when the process pressure is 0.15 Torr, the number corresponded to 0.244/cm². When the process pressure is 3.5 Torr, the number corresponded to 0.318/cm². When the process pressure is 7.6 Torr, the number corresponded to 67.7/cm². Herein, oxidized or crystallized parts on the surface of a tungsten layer were counted as particles. That is, the number of particles may be used as a judgment standard of oxidation selectivity. As the above measurement result of the number of particles, the number of particles is too large when the process pressure is 7.6 Torr. In other words, the surfaces of the tungsten layers are considerably oxidized. Thus, under this process pressure, a desired selective oxidation process can not be achieved.

On the other hand, when the process pressure is not higher than 3.5 Torr, the number of particles is very small. In other words, the surfaces of the tungsten layers are scarcely oxidized. Thus, when the process pressure is not higher than 3.5 Torr, a selective oxidation process can be achieved with a sufficient selectivity. In the case, from the graph shown in FIG. 2, it can be found that it is particularly preferable to set the process pressure not higher than 1 Torr so that the oxidation by the active oxygen species and the active hydroxyl species is dominant. Herein, the lower limit of the process pressure is about 0.1 Torr, taking into consideration the lower limit of throughput.

<Evaluation Experiment 2>

Next, as an evaluation experiment 2, a relationship between H₂-gas density in total flow rate of the O₂ gas and the H₂ gas and selectivity was evaluated.

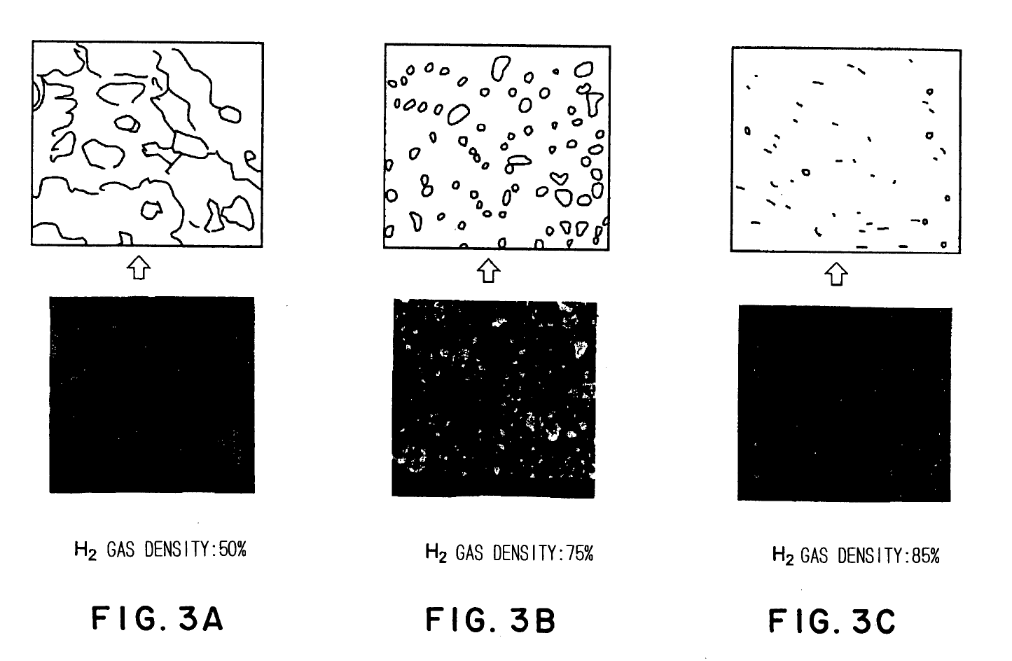

FIGS. 3A to 3C are electron microscope photographs and their sketches showing surfaces of tungsten layers when the H₂-gas density is variously changed for the total flow rate of gases.

Herein, the total flow rate of the O₂ gas and the H₂ gas was fixed to 2000 sccm, and the density of the H₂ gas was changed between 50%, 75% and 85%. Regarding the other process conditions, the process temperature was 850° C., the process pressure was 0.35 Torr (47 Pa), which is within a pressure range defined by the above evaluation experiment 1, and the processing time was 20 minutes.

At first, in the respective H₂-gas densities, SiO₂ films were formed on the surfaces of the silicon layers at sufficient large film-forming rates. On the other hand, as shown in FIG. 3A, when the H₂-gas density was 50%, large crystals of tungsten oxide films (WO₃) were found on the surfaces of the tungsten layers. That is, it was confirmed that, when the H₂-gas density is 50%, not only the silicon layers but also the tungsten layers are considerably oxidized so that a selective oxidation process with a sufficient selectivity can not be achieved.

As shown in FIG. 3B, when the H₂-gas density was 75%, only very micro crystals of tungsten oxide films were found on the surfaces of the tungsten layers. That is, it was confirmed that, when the H₂-gas density is 75%, the surfaces of the silicon layers are oxidized but the surfaces of the tungsten layers are only slightly oxidized and remain as metal tungsten in most so that a selective oxidation process with a sufficient selectivity can be achieved.

As shown in FIG. 3C, when the H₂-gas density was 85%, the surfaces of the tungsten layers are scarcely oxidized and still remain as metal tungsten. That is, it was confirmed that, when the H₂-gas density is 85%, the surfaces of the silicon layers are oxidized but the surfaces of the tungsten layers are scarcely oxidized so that a selective oxidation process with a high selectivity can be achieved.

As a result, in order to carry out a selective oxidation process with a sufficient high selectivity, it was confirmed that it is necessary to set the H₂-gas density at 75% or more with respect to the total flow rate of the process gases to make a hydrogen-rich state, preferably to set the H₂-gas density at 85% or more. In the case, the upper limit of the H₂-gas density is less than 100%. Taking into consideration the film-forming rates of the oxide films formed on the surfaces of the silicon layers and the throughput, the practical upper limit of the H₂-gas density is about 95%. In addition, in the respective H₂-gas densities, generation of bird's beaks was not found. That is, it was confirmed that generation of bird's beaks is also inhibited.

<Evaluation Experiment 3>

Next, in order to confirm a crystal structure, an X-ray was irradiated onto the surfaces of the tungsten layers of FIGS. 3A to 3C, so that X-ray diffraction spectrums were evaluated.

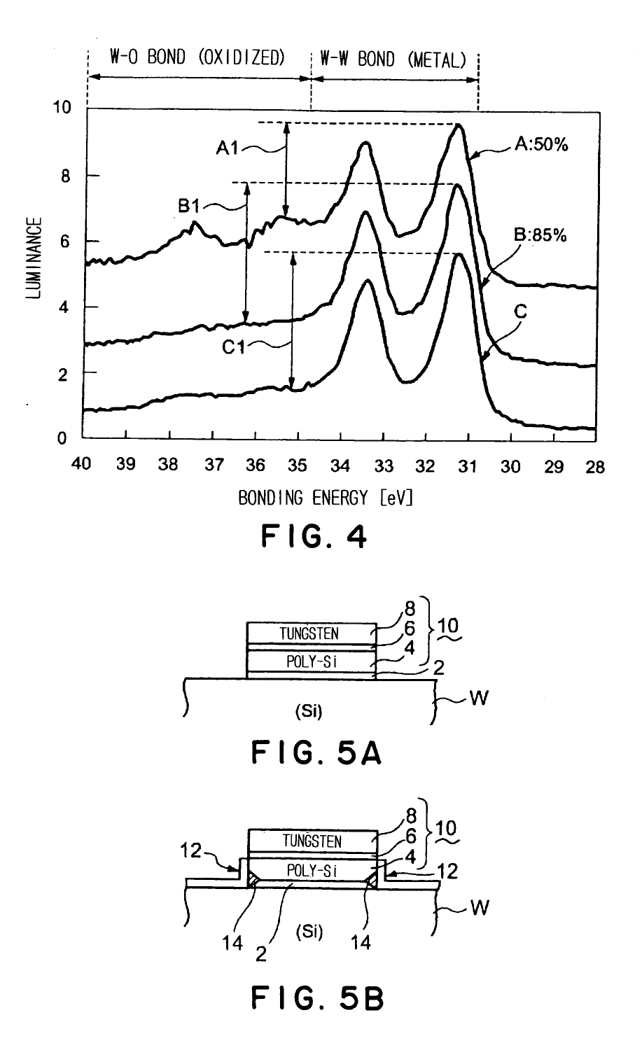

FIG. 4 is a graph showing X-ray diffraction spectrums obtained when the X-ray was irradiated on the surfaces of the tungsten layers. In the drawing, characteristics A show a case wherein the H₂-gas density is 50%, characteristics B show a case wherein the H₂-gas density is 85%, and characteristics C show characteristics of a metal tungsten surface as a standard. In addition, characteristics of a case wherein the H₂-gas density is 75% are omitted.

In FIG. 4, a peak between 30 eV and 35 eV of binding energy corresponds to a [W—W] bond (metal state), and a peak between 35 eV and 40 eV corresponds to a [W—O] bond (oxidized state). A larger difference of heights of the both peaks means higher selectivity of the oxidation process. Herein, regarding luminance in the longitudinal axis, the respective characteristics A to C are vertically shifted.

As shown in FIG. 4, in an area between 30 eV and 35 eV of binding energy, each of all the characteristics A to C has two large peaks of [W—W] bonds. On the other hand, in an area between 35 eV and 40 eV of binding energy, the characteristics A have two small peaks of [W—O] bonds, but the characteristics B and C have no substantial peak. That is, in the characteristics B and C, it may be said that there is no tungsten oxide film. In FIG. 4, the peak difference of the characteristics A is shown by “A1”, the peak difference of the characteristics B is shown by “B1” and the peak difference of the characteristics C is shown by “C1”. The peak difference A1 is small, that is, the oxidation selectivity is small. However, the peak difference B1 is large, and substantially the same as the peak difference C1 of the standard characteristics C. Thus, as a result, it was confirmed that the oxidation selectivity by the characteristics B is very high.

In the above embodiment, each of the gas ejecting nozzles 64 and 66 has one gas ejecting port. However, this invention is not limited thereto. For example, a so-called dispersion-type of gas ejecting nozzle may be used, which has a linear glass tube arranged in a longitudinal direction in the processing container 22 and a plurality of gas ejecting ports provided at the glass tube at a predetermined pitch. In addition, the processing container 22 is not limited to the single tube structure, but may be a processing container having a double tube structure consisting of an inner tube and an outer tube.

In addition, in the above embodiment, the O₂ gas is used as an oxidative gas. However, this invention is not limited thereto. An N₂O gas, an NO gas, an NO₂ gas and the like may be used. In addition, in the above embodiment, the H₂ gas is used as a reducing gas. However, this invention is not limited thereto. An NH₃ gas, a CH₄ gas, an HCl gas and the like may be used.

In addition, this invention is applicable to an LCD substrate, a glass substrate or the like, as an object to be processed, instead of the semiconductor wafer.

1. An oxidizing method for an object to be processed, the oxidizing method comprising:
an arranging step of arranging a plurality of objects to be processed in a processing container whose inside can be vacuumed, the processing container having a predetermined length, a supplying unit of an oxidative gas and a supplying unit of a reducing gas being provided at the processing container, each of the plurality of objects to be processed having an exposed silicon layer and an exposed tungsten layer;
an active-species forming step of supplying the oxidative gas and the reducing gas into the processing container, causing the both gases to react on each other under a reduced pressure, and generating active oxygen species and active hydroxyl species in the processing container; and
an oxidizing step of oxidizing surfaces of the silicon layers of the plurality of objects to be processed by means of the active species.

2. An oxidizing method for an object to be processed according to claim 1, wherein
the oxidizing step is conducted under a process pressure not higher than 466 Pa (3.5 Torr).

3. An oxidizing method for an object to be processed according to claim 1 or 2, wherein
density of the reducing gas in total of the oxidative gas and the reducing gas is not less than 75% and less than 100%.

4. An oxidizing method for an object to be processed according to any of claims 1 or 2, wherein
the oxidizing step is conducted under a process temperature within a range of 450° C. to 900° C.

5. An oxidizing method for an object to be processed according to any of claims 1 or 2, wherein
the oxidative gas includes one or more gases selected from a group consisting of O₂, N₂O, NO, NO₂ and O₃, and
the reducing gas includes one or more gases selected from a group consisting of H₂, NH₃, CH₄, HCl and deuterium.

6. An oxidizing unit comprising:
a processing container whose inside can be vacuumed, the processing container having a predetermined length;
a supplying unit of an oxidative gas that supplies an oxidative gas into the processing container;
a supplying unit of an reducing gas that supplies a reducing gas into the processing container;
a holding unit that supports a plurality of objects to be processed at a predetermined pitch, and that can be arranged in the processing container, each of the plurality of objects to be processed having an exposed silicon layer and an exposed tungsten layer; and
a controlling unit that controls the supplying unit of an oxidative gas and the supplying unit of an reducing gas so as to control respective supply flow rates of the oxidative gas and the reducing gas into the processing container in such a manner that the silicon layers of the plurality of objects to be processed are selectively oxidized.

7. A controlling unit for controlling an oxidizing unit including: a processing container whose inside can be vacuumed, the processing container having a predetermined length; a supplying unit of an oxidative gas that supplies an oxidative gas into the processing container; a supplying unit of an reducing gas that supplies a reducing gas into the processing container; and a holding unit that supports a plurality of objects to be processed at a predetermined pitch, and that can be arranged in the processing container, each of the plurality of objects to be processed having an exposed silicon layer and an exposed tungsten layer;
the controlling unit being adapted to control the supplying unit of an oxidative gas and the supplying unit of an reducing gas so as to control respective supply flow rates of the oxidative gas and the reducing gas into the processing container in such a manner that the silicon layers of the plurality of objects to be processed are selectively oxidized.

8. A program for controlling an oxidizing unit including: a processing container whose inside can be vacuumed, the processing container having a predetermined length; a supplying unit of an oxidative gas that supplies an oxidative gas into the processing container; a supplying unit of an reducing gas that supplies a reducing gas into the processing container; and a holding unit that supports a plurality of objects to be processed at a predetermined pitch, and that can be arranged in the processing container, each of the plurality of objects to be processed having an exposed silicon layer and an exposed tungsten layer;
the program being adapted to cause a computer to execute:
a controlling procedure for controlling the supplying unit of an oxidative gas and the supplying unit of an reducing gas so as to control respective supply flow rates of the oxidative gas and the reducing gas into the processing container in such a manner that the silicon layers of the plurality of objects to be processed are selectively oxidized.

9. A storage medium capable of being read by a computer, storing a program for controlling an oxidizing unit including: a processing container whose inside can be vacuumed, the processing container having a predetermined length; a supplying unit of an oxidative gas that supplies an oxidative gas into the processing container; a supplying unit of an reducing gas that supplies a reducing gas into the processing container; and a holding unit that supports a plurality of objects to be processed at a predetermined pitch, and that can be arranged in the processing container, each of the plurality of objects to be processed having an exposed silicon layer and an exposed tungsten layer;
the program being adapted to cause a computer to execute:
a controlling procedure for controlling the supplying unit of an oxidative gas and the supplying unit of an reducing gas so as to control respective supply flow rates of the oxidative gas and the reducing gas into the processing container in such a manner that the silicon layers of the plurality of objects to be processed are selectively oxidized.

10. A storage medium capable of being read by a computer, storing software for controlling an oxidizing method for an object to be processed,
the oxidizing method comprising:
an arranging step of arranging a plurality of objects to be processed in a processing container whose inside can be vacuumed, the processing container having a predetermined length, a supplying unit of an oxidative gas and a supplying unit of a reducing gas being provided at the processing container, each of the plurality of objects to be processed having an exposed silicon layer and an exposed tungsten layer;
an active-species forming step of supplying the oxidative gas and the reducing gas into the processing container, causing the both gases to react on each other under a reduced pressure, and generating active oxygen species and active hydroxyl species in the processing container; and
an oxidizing step of oxidizing surfaces of the silicon layers of the plurality of objects to be processed by means of the active species.
